(19) United States
(12) Patent Application Publication
(10) Pub. No.: US 2008/0237882 A1
(43) Pub. Date: Oct. 2, 2008

(54) Annular via drilling (AVD) technology

(76) Inventor: Islam Salama, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/731,432

(22) Filed: Mar. 30, 2007

(51) Int. Cl. H01L 23/52; H01L 21/44

(52) U.S. Cl. 257/774; 438/675; 257/E23.141

(57) ABSTRACT

In some embodiments, annular via drilling (AVD) technology is presented. In this regard, an annular via is introduced comprising an inner wall and an outer wall, the inner wall and the outer wall coupled with a dielectric layer and extending linearly from a surface of a conductor to a top of the dielectric layer. Other embodiments are also disclosed and claimed.

### FIELD OF THE INVENTION

Embodiments of the present invention generally relate to the field of integrated circuit package vias, and, more particularly to annular via drilling (AVD) technology.

### BACKGROUND OF THE INVENTION

Lasers are commonly used in to remove material during integrated circuit package fabrication. Typically, laser drilling removes a cone-shaped portion of dielectric material which is plated and then laminated to replace the material removed, forming a via that provides vertical interconnection between layers. One potential problem, however, is that the plug material may not provide a coefficient of thermal expansion (CTE) equal to that of the material removed.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of a partially formed IC package substrate, in accordance with one example embodiment of the invention;

FIG. 2 is a graphical illustration of a cross-sectional view of a partially formed IC package substrate, in accordance with one example embodiment of the invention;

FIG. 3 is a graphical illustration of a cross-sectional view of a partially formed IC package substrate, in accordance with one example embodiment of the invention;

FIG. 4 is a flow chart of an example method for annular via drilling, in accordance with one example embodiment of the invention; and

FIG. 5 is a block diagram of an example electronic appliance suitable for implementing an IC package substrate with annular via drilling technology, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of a partially formed IC package substrate, in accordance with one example embodiment of the invention. In accordance with the illustrated example embodiment, package substrate 100 includes one or more of substrate core 102, dielectric material 104, internal copper conductor 106, conductor surface 108, and dielectric surface 110.

Substrate core 102 represents a substrate core that may be made of a solid metal such as copper or may comprise multiple conductive layers laminated together. Substrate core 102 may be laminated with dielectric material as part of a substrate build-up and may have insulated traces routed through it.

Dielectric material 104 represents material such as epoxy resin that has been added to substrate core 102 as part of a build-up process. Conductive traces may be routed within and through-holes may be routed through dielectric material 104 and/or core layer 102. Internal copper conductor 106 is intended to represent a conductive trace embedded within dielectric material 104.

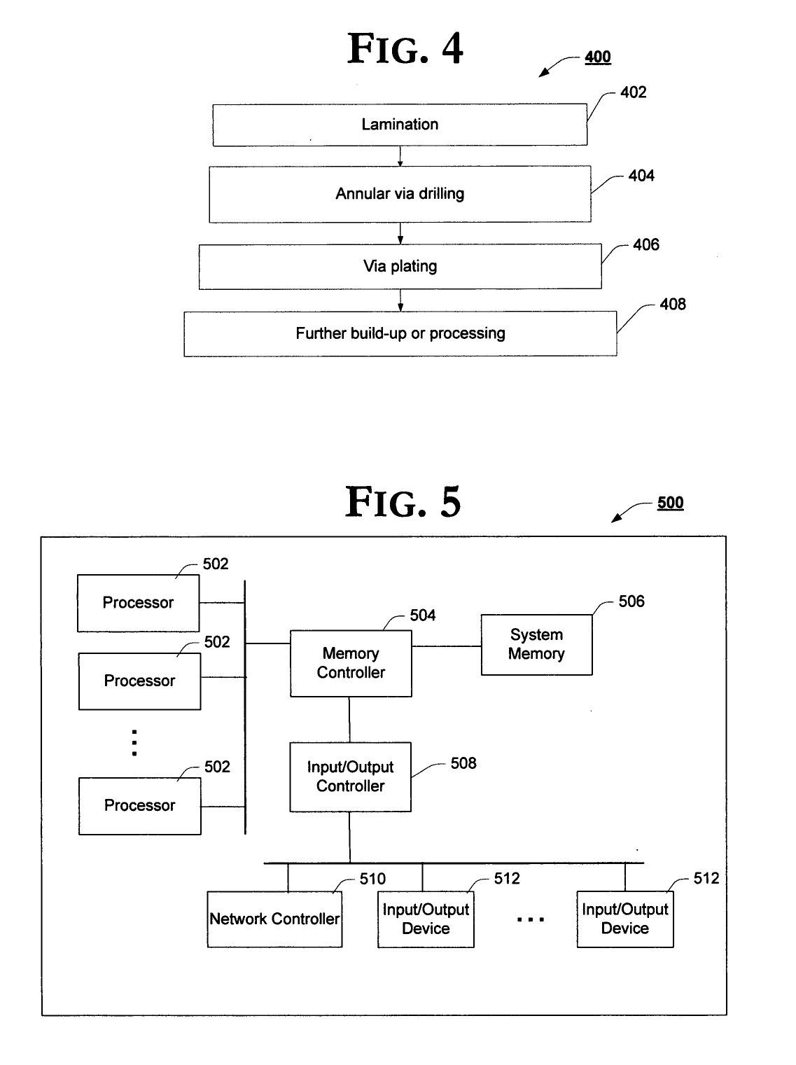

FIG. 2 is a graphical illustration of a cross-sectional view of a partially formed IC package substrate, in accordance with one example embodiment of the invention. As part of a process for annular via drilling, for example as described in reference to FIG. 4, annular via 202 is formed in dielectric material 104.

Annular via 202 includes inner wall 204 and outer wall 206, both adjacent to dielectric layer 104 and both extending linearly from dielectric surface 110 down to conductor surface 108. In one embodiment, inner wall 204 and outer wall 206 extend parallel to each other, thereby providing annular via 202 with a uniform thickness.

In one embodiment, annular via 202 represents a continuous circular (when viewed from above) via of diminishing radius extending inwardly from dielectric surface 110 to conductor surface 108. In another embodiment, annular via 202 represents a discontinuous circular shape. In still other embodiment, annular via 202 need not be circular and may be any polygonal shape, either continuous or discontinuous. The shape of annular via 202 may be achieved by moving a laser over dielectric layer 104, by moving substrate 100 under a laser, or by a combination of both. The present invention is not limited to any particular optics design.

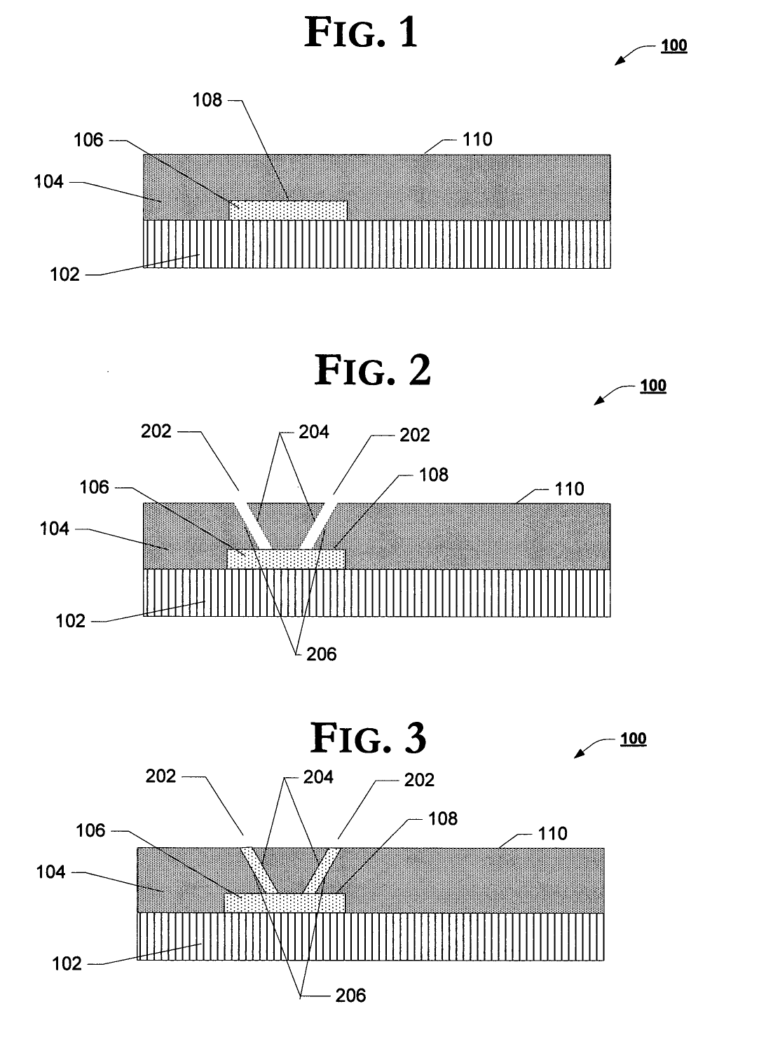

FIG. 3 is a graphical illustration of a cross-sectional view of a partially formed IC package substrate, in accordance with one example embodiment of the invention. As shown, plating, such as copper plating, has been added to annular via 202. In one embodiment, annular via 202 is electroplated. In another embodiment, annular via 202 is electro-less plated. One skilled in the art would appreciate that plated annular via 202 is substantially flush with dielectric surface 110 and that dielectric material 104 inside of inner wall 204 has not been disturbed, thereby saving processing steps.

In one embodiment, package substrate 100 is coupled with an integrated circuit die such as a flip chip microprocessor die through a copper bump formed on annular via 202. In another embodiment, package substrate 100 is laminated with another dielectric layer as part of a continued build-up process. In another embodiment, package substrate 100 includes build-up layers having multiple annular vias stacked concentrically on top of one another. In another embodiment, package substrate 100 represents a high density interconnect (HDI) substrate with embedded thin film active or passive devices (not shown).

FIG. 4 is a flow chart of an example method for annular via drilling, in accordance with one example embodiment of the invention. It will be readily apparent to those of ordinary skill in the art that although the following operations may be described as a sequential process, many of the operations may in fact be performed in parallel or concurrently. In addition, the order of the operations may be re-arranged or steps may be repeated without departing from the spirit of embodiments of the invention.

According to but one example implementation, the method of FIG. 4 begins with lamination (402) of dielectric material 104 on substrate core 102 (and conductor 106).

Next, annular via drilling (404) in dielectric material 104 occurs, forming annular via 202.

Next, annular via 202 is plated (406), for example with copper.

Lastly, further build-up and processing (408) is performed on substrate 100. Additional steps may be needed to complete the substrate, such as forming a copper bump coupled with annular via 202, and to couple the substrate with a microprocessor die, before the processor package can be placed in an electronic device, such as shown in FIG. 5.

FIG. 5 is a block diagram of an example electronic appliance suitable for implementing an IC package substrate with annular via drilling technology, in accordance with one example embodiment of the invention. Electronic appliance 500 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 500 may include one or more of processor(s) 502, memory controller 504, system memory 506, input/output controller 508, network controller 510, and input/output device(s) 512 coupled as shown in FIG. 5. Processor(s) 502, or other integrated circuit components of electronic appliance 500, may be housed in a package including a substrate described previously as an embodiment of the present invention.

Processor(s) 502 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 502 are Intel® compatible processors. Processor(s) 502 may have an instruction set containing a plurality of machine level instructions that may be invoked, for example by an application or operating system.

Memory controller 504 may represent any type of chipset or control logic that interfaces system memory 508 with the other components of electronic appliance 500. In one embodiment, the connection between processor(s) 502 and memory controller 504 may be referred to as a front-side bus. In another embodiment, memory controller 504 may communicate on a point-to-point link.

System memory 506 may represent any type of memory device(s) used to store data and instructions that may have been or will be used by processor(s) 502. Typically, though the invention is not limited in this respect, system memory 506 will consist of dynamic random access memory (DRAM). In one embodiment, system memory 506 may consist of Rambus DRAM (RDRAM). In another embodiment, system memory 506 may consist of double data rate synchronous DRAM (DDRSDRAM).

Input/output (I/O) controller 508 may represent any type of chipset or control logic that interfaces I/O device(s) 512 with the other components of electronic appliance 500. In one embodiment, I/O controller 508 may be referred to as a south bridge. In another embodiment, I/O controller 508 may comply with the Peripheral Component Interconnect (PCI) Express™ Base Specification, Revision 1.0a, PCI Special Interest Group, released Apr. 15, 2003.

Network controller 510 may represent any type of device that allows electronic appliance 500 to communicate with other electronic appliances or devices. In one embodiment, network controller 510 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 510 may be an Ethernet network interface card.

Input/output (I/O) device(s) 512 may represent any type of device, peripheral or component that provides input to or processes output from electronic appliance 500.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a conductor;
a dielectric layer laminated to a surface of the conductor; and
an annular via comprising an inner wall and an outer wall, the inner wall and the outer wall coupled with the dielectric layer and extending linearly from the surface of the conductor to a top of the dielectric layer.

2. The apparatus of claim 1, further comprising the inner wall and the outer wall extending parallel to each other.

3. The apparatus of claim 1, wherein the annular via comprises a discontinuous circle.

4. The apparatus of claim 1, wherein the annular via comprises a polygon.

5. The apparatus of claim 1, further comprising the annular via extending inwardly from the top of the dielectric layer to surface of the conductor.

6. The apparatus of claim 1, further comprising a copper bump coupled with the via.

7. The apparatus of claim 6, further comprising a microprocessor die coupled with the copper bump.

8. The apparatus of claim 7, further comprising:
a network controller; and
a system memory.

9. A method comprising:
laminating a dielectric layer on a surface of a conductor;
laser drilling an annular via comprising an inner wall and an outer wall, the inner wall and the outer wall coupled with the dielectric layer and extending linearly from a top of the dielectric layer to the surface of the conductor; and
plating the via.

10. The method of claim 9, further comprising laser drilling the inner wall and the outer wall parallel to each other.

11. The method of claim 9, wherein laser drilling the via comprises laser drilling a discontinuous circle.

12. The method of claim 9, wherein laser drilling the via comprises laser drilling a polygon.

13. The method of claim 9, further comprising forming a copper bump coupled with the annular via.

14. The method of claim 13, further comprising coupling a microprocessor die to the copper bump to form a processor package.

15. The method of claim 14, further comprising placing the processor package in an electronic device including a system memory and a network controller.
